(19) United States
(12) Patent Application Publication
(10) Pub. No.: US 2016/0044826 A1
(43) Pub. Date: Feb. 11, 2016

(54) ELECTRONICS PROTECTION HOUSING FOR ACCOMMODATING ELECTRONICS

(71) Applicant: PRIMETALS TECHNOLOGIES AUSTRIA GMBH, Linz (AT)

(72) Inventors: Franz HARTL, Linz (AT); Manuel HARTL, St. Johann am Wimberg (AT); Thomas KUEHAS, Luftenberg (AT); Martin LEHOFER, Plainsboro, NJ (US); Andreas ROHRHOFER, Linz (AT); Michael WEINZINGER, Linz (AT)

(21) Appl. No.: 14/779,574

(22) PCT Filed: Mar. 11, 2014
(86) PCT No.: PCT/EP2014/054641

§ 371 Date: Sep. 24, 2015

(30) Foreign Application Priority Data
Mar. 26, 2013 (EP) 13161049.5

(51) Int. Cl. H05K 7/20; H02K 7/18; H05K 5/02; H01L 41/053

(52) U.S. Cl. CPC H05K 7/2039; H05K 7/20009; H05K 7/20218; H01L 41/053; H02K 7/1823; H05K 5/0213

(57) ABSTRACT

An electronics protection housing which reliably protects electronics (1) therein from heat or hot liquids has an inner housing part (2) at least partially enclosing the electronics (1) and at least one outer housing part (3) at least partially enclosing the inner housing part (2) and which can be fastened on the inner housing part (2) by a mechanically removable connection, wherein the at least one outer housing part (3) has at least one layer having a renewable raw material, wherein the inner housing part (2) has at least one layer having a material having a temperature resistance of at least up to 150° C.

### CROSS-REFERENCE TO RELATED APPLICATIONS

The present application is a 35 U.S.C. §§371 national phase conversion of PCT/EP2014/054641, filed Mar. 11, 2014, which claims priority of European Patent Application No. 13161049.5, filed Mar. 26, 2013, the contents of which are incorporated by reference herein. The PCT International Application was published in the German language.

### BACKGROUND OF THE INVENTION

The invention relates to an electronics protection housing for accommodating electronics.

For example, such a device is used for electronic components in hot regions or on bodies with extreme temperature radiation.

For example, such an electronics protection housing may be used in the case of metallurgical containers, e.g. converters, for protecting electronics which register physical monitoring variables of the liquid pig iron or steel bath in the converter. In addition to applications in the field of steelworking, such an electronics protection housing may also be used in the manufacture of cement, e.g. by means of a rotating tubular kiln, or in the context of other industrial processes which take place at high temperature.

### SUMMARY OF THE INVENTION

The object of the invention is to provide an electronics protection housing which reliably protects electronics therein from heat or hot liquids or solids.

This object is achieved by means of an electronics protection housing of the type cited in the introduction, in that the electronics protection housing has an inner housing part, which at least partially encloses the electronics, and at least one outer housing part, which at least partially encloses the inner housing part and which can be fastened to the inner housing part by a mechanically removable connection. The at least one outer housing part has at least one layer comprising a renewable raw material, and the inner housing part has at least one layer comprising a material having a temperature resistance of at least up to 150° C.

Said object is also achieved by a system including the housing.

In this case, the at least one outer housing part can be considered as an expendable part or expendable shell, which may also have a plurality of layers comprising a renewable raw material, like an onion shell. The at least one outer housing part and/or the inner housing part is preferably configured such that a simple exchange can be effected in as short a time as possible. In order to achieve this, the mechanically removable connection can be designed as a plug-type connection or a screw connection, for example. This connection may be incorporated in the at least one outer housing part and/or the inner housing part, for example.

Particularly good results can be achieved if the at least one outer housing part or the layer comprising a renewable raw material is treated such that the at least one outer housing part or the layer have enhanced flame resistance and/or thermal insulation properties. A suitable impregnation can be used for this purpose, for example.

By virtue of the material which is resistant up to at least 150° C., the inner housing part preserves the structural integrity of the electronics protection housing and at the same time offers good insulation properties, in particular thermal and/or electrical insulation properties. The inner housing part also allows mechanical protection of the electronics.

The proposed electronics protection housing enables electronic components to be operated reliably over extended periods in hot regions or on bodies with extreme temperature radiation. Instead of electronics in such environmental conditions being operated purely manually for only short periods or periodically at specific intervals as before, the proposed electronics protection housing allows long-lasting and inexpensive installation of the electronics in harsh and hot environments. Very affordable materials can be used for the outer housing part and/or the inner housing part, and therefore the proposed solution is also inexpensive.

The electronics protection housing in particular allows long-lasting operation of electronics in the vicinity of metallurgical vessels and in other fields of use having a significantly raised ambient temperature. The inner housing part and the electronics disposed therein have extended durability in this case. At the same time, the electronics protection housing is inexpensive.

In the vicinity of a metallurgical vessel, for example, unless this can be reliably prevented, splashes of liquid metal or similar from the vessel will reach the electronics protection housing, infrared radiation from the vessel will act on the electronics protection housing, or a hot stream of waste gas or smoke from the vessel will act on the electronics protection housing. In particular, a significantly raised ambient temperature is present if the electronics protection housing is exposed at least partially or at least sectionally to a temperature of at least 150° C., in particular at least 200° C. Long-lasting operation here means that the electronics can be operated over extended periods, in particular over several days, in the environmental conditions cited above. To this end, in particular, it may be necessary occasionally to exchange the at least one outer housing part as soon as it is worn or worn out.

In an advantageous embodiment of the invention, the at least one inner housing part and the at least one outer housing part are at least sectionally permeable to radio waves for the purpose of wireless communication.

The electronics protection housing can therefore be designed such that the electronics therein are able to communicate wirelessly with communication stations arranged outside the electronics protection housing. Before now, it was often impossible to realize solutions featuring wireless communication, particularly in the case of a mobile or displaceable electronics protection housing or electronics of this type. This is because metal housings were often used for electronics protection housings in the past, and therefore data transfer was realized with the aid of slip rings, rotary ducts, trailing cables and similar cable-based devices instead of wireless communication. However, the electronics protection housing according to this advantageous embodiment has at least one outer housing part and at least one inner housing part which are at least sectionally permeable to radio waves, thereby allowing wireless communication. It is therefore possible to dispense with the cited cable-based communication means. This represents a cost advantage and requires less maintenance expense.

In a further advantageous embodiment of the invention, a protective gas is provided within the outer housing part and/or within the inner housing part. The protective gas may comprise one or more noble gases, for example, wherein e.g. carbon dioxide and/or helium or mixtures of said gases may also be used. The protection of the electronics can be further improved by the protective gas.

In a further advantageous embodiment of the invention, the at least one layer comprising a renewable raw material includes wood, wood foam, paperboard, cardboard, a fiberboard composite material or a mixture of at least two of these materials.

Wood foam can be made from wood sawdust or cellulose, for example, possibly with the addition of cereal flour. In this case, an aerating agent such as yeast is used for the purpose of foaming. The wood foam is then obtained by baking the selected wood components with the added aerating agent. An epoxy resin may also be added to the wood foam as an option.

The respective renewable raw material or mixture may be so treated as to have very good flame resistance and insulation properties in this case, e.g. by pressure compacting the material to form a particularly dense material and/or by means of a flame-resistant and/or electrically insulating impregnation or coating. It is also possible to use e.g. cross laminated timbers (CLT), which are known as particularly fire-resistant supporting beams from the field of construction and offer greater fire resistance than many other materials, in particular many types of steel.

It is advantageous that the cited renewable raw materials can be obtained very inexpensively, and therefore a worn outer housing part can be replaced very inexpensively. Furthermore, these raw materials have a particularly advantageous climatic balance since they are CO2-neutral.

In a further advantageous embodiment of the invention, the at least one layer comprising the material having a temperature resistance of at least up to 150° C. includes polytetrafluoroethylene, polyphenylene sulfide, silicone rubber, polyimide, ethylene propylene copolymer, cyclic olefin copolymer, polyetherimide, polyethersulfone, polyhydroxyalkanoate, polyhydroxybutyrate, polysulfone, or a mixture of at least two of these materials.

The cited synthetic materials have good temperature resistance, and can therefore reliably protect the housing from heat and/or hot liquids or solids when used in the inner housing part. This is achieved because the corresponding synthetic material layer retains its shape and its physical properties, in particular its insulation properties. For applications characterized by particularly high temperatures, silicone rubber with a temperature resistance up to 200° C., polyphenylene sulfide (up to 240° C.), polyimide (up to 280° C.), ethylene propylene copolymer (up to 300° C.) and polytetrafluoroethylene (PTFE, up to 350° C.) may be used in particular. In this case, PTFE is particularly suitable for use under the most adverse conditions due to its notable heat resistance, good insulation properties and good chemical resistance. PTFE is moreover hydrophobic, hard, tough and at the same time very inexpensive.

In a further advantageous embodiment of the invention, provision is made for at least one medium line, which leads from outside the electronics protection housing into the inner housing part and in which a medium can flow. In particular, the at least one medium line may be a medium line which is required for the operation of the plant. The medium line may be routed through the electronics protection housing, for example. This line may be used to carry a cooling medium, e.g. water that is used for cooling the plant, or gaseous mediums such as e.g. oxygen or other gases which are used as process gases or circulation gases in the plant. The electronics protection housing may also be provided with a medium line whose sole purpose is to ensure the cooling of the electronics protection housing.

In particular in an environment with high temperature radiation, such as e.g. converters in the field of steelworking or in rotating tubular kilns for cement manufacture, the cooling of the electronics represents a significant problem. Until now, this problem has often been solved by actively intervening in existing medium networks in such a way that mediums are consumed or lost in this case. Therefore pressure testing of the medium or medium line is often necessary in existing solutions.

In this case, the medium line that is routed into the inner housing part may be an existing medium line which is used for cooling the converter or the rotating tubular kiln, for example. It is advantageous in this case that the electronics protection housing can be attached to the medium line and the medium line is fluid-impermeable relative to the electronics protection housing, such that heat transfer into the liquid or gaseous medium is possible while at the same time no medium can be lost from the line. In comparison with solutions in which mediums are lost, a cost advantage is therefore derived during the manufacture and/or installation of the electronics protection housing because pressure testing of the medium line is not required, and a cost advantage is derived during live operation because no medium is lost. This offers particularly significant advantages when operating the electronics protection housing in an explosive environment, since the avoidance of medium loss represents a safety advantage, particularly in relation to hydrogen explosions.

As a result of at least one medium line passing through the electronics protection housing, the temperature resistance of said housing can be further increased in this case. Mediums which may be used to pass through said housing include liquid nitrogen, liquid argon, cooling water, oil, air or a protective gas, for example.

In a further advantageous embodiment of the invention, the electronics protection housing has a first heat sink, to which the electronics can be thermally connected and to which the connected electronics can release waste heat.

The first heat sink allows efficient removal of the waste heat of the electronics and heat which has entered or penetrated the electronics protection housing from outside, and therefore allows an extended service life of the electronics since the electronics can be reliably protected from overheating. This is achieved by reliably cooling particularly hot locations or hotspots of the electronics, for example. The first heat sink is preferably made of a heat-conductive material such as copper or aluminum in this case.

In a further advantageous embodiment of the invention, the at least one medium line is so arranged at the first heat sink that the first heat sink can release waste heat to the cooling medium in this case.

In particular, the arrangement of the at least one medium line at the first heat sink is such that a thermal contact is present between both elements in this case. This ensures a particularly efficient removal of the waste heat of the electronics, whereby the service life of the electronics can be significantly increased. At the same time, the temperature of the inner housing part and/or of the at least one outer housing part can also be reduced, such that the electronics protection housing overall, and in particular the at least one outer housing part, can be used for a longer time.

In a further advantageous embodiment of the invention, the electronics protection housing has a second heat sink in this case, wherein the at least one medium line is so arranged at the second heat sink that the second heat sink can release waste heat to the medium, wherein an insulation layer comprising a synthetic material having a temperature resistance of at least up to 150° C. is arranged between the first heat sink and the second heat sink.

The temperature of the inner housing part can be further reduced by virtue of the second heat sink, wherein the insulation layer ensures that the waste heat of the electronics is not ultimately released to the rest of the electronics protection housing via the first heat sink and the second heat sink. If the second heat sink is in thermal contact with the inner housing part and/or the at least one outer housing part, and the respective housing part is heated or hot as a result of hot environmental conditions of the electronics protection housing, it is therefore also possible effectively to prevent the heat from outside the electronics protection housing from ultimately being conducted to the electronics via the at least one outer housing part and/or the inner housing part and then the second heat sink and the first heat sink. Therefore the insulation layer, which is made of e.g. PTFE, provides an effective thermal separation of the two heat sinks, thereby resulting generally in an extended service life of the electronics and/or the electronics protection housing.

In a further advantageous embodiment of the invention, the electronics protection housing comprises a Peltier element by means of which the electronics can be supplied, wherein one side of the Peltier element is in thermal contact with the at least one medium line.

If one side of the Peltier element is attached to the at least one medium line, a large temperature difference can be tapped by the Peltier element, e.g. because the other side of the Peltier element is in thermal contact with as hot as possible a point inside or outside the electronics protection housing. In a particularly advantageous embodiment, therefore, the other side of the Peltier element is thermally connected to the electronics or to a hot side surface of the housing. As a result of the attachment to two points having a temperature difference, the Peltier element generates an electric current in accordance with the Seebeck effect, and this can be supplied to the electronics.

In this case, use of the Peltier element allows a reliable supply to the electronics without having to route cables into the electronics protection housing, wherein said cables could be damaged or break in the harsh operating environment of the electronics protection housing. Also advantageous in this case is the modest size of the Peltier element and the absence of moving components which might be subject to wear. In particular, this makes it possible to dispense with electrical supply cables which are routed into the electronics protection housing from outside, and to perform the communication with the electronics wirelessly.

In a further advantageous embodiment of the invention, the electronics protection housing has a turbine which is rotatably disposed in the at least one medium line, and means for converting a rotational movement of the turbine into electrical energy, wherein the electronics can be supplied by the turbine and the means for conversion.

The turbine may have a simple impeller wheel, for example, which generates a rotation of the impeller wheel from the flow movement of the cooling medium. This rotation can then be converted by the means, e.g. a generator or a dynamo, into electrical energy which can be used to supply the electronics. This then allows the electronics to be supplied without additional cables which are routed into the electronics protection housing, this being advantageous in the harsh operating environment of the electronics protection housing.

In a further advantageous embodiment of the invention, the electronics protection housing comprises means for converting mechanical energy of the electronics protection housing into electrical energy for supplying the electronics.

The electronics protection housing may be used to measure physical monitoring variables, for example, particularly in the case of a converter or a rotating tubular kiln, for which purpose the electronics protection housing is moved. The movement may also be caused by jolts when metallurgical vessels are deposited by a hall crane, by the rotation of the converter or the rotating tubular kiln, or during the movement of plant vehicles, these being coupled to the electronics protection housing in each case.

The means for converting mechanical energy into electrical energy uses this movement to generate electrical energy which can be supplied to the electronics. An “energy harvesting” method is therefore used to supply the electronics, whereby it is again possible to dispense with additional cables which are routed into the electronics protection housing.

In a further advantageous embodiment of the invention, the means for converting mechanical energy of the electronics protection housing into electrical energy are embodied as a piezoelectric element and/or as a dielectric elastomer in this case.

Both the piezoelectric element and the dielectric elastomer can provide electrical energy as a result of being moved. In this case, the movement may take the form of a vibration or translation, etc. For example, a gyrating mass may be provided for this purpose within the electronics protection housing, in order to further improve the efficiency of the supply to the electronics protection housing. In this case, it is also conceivable to arrange the piezoelectric element and/or the dielectric elastomer in the vicinity of or in direct contact with a medium line which is provided if applicable, such that vibrations of the medium line can be used to capture electrical energy.

Provision may also be made for a buffer battery which can ensure a supply to the electronics even if an adequate power supply is not provided by the Peltier element, the turbine, the generator and/or the piezoelectric element due to the operating state of the plant.

In a further advantageous embodiment of the invention, the electronics protection housing has means for registering wear of the at least one outer housing part.

As a result of registering wear of the at least one outer housing part, it is possible to replace the at least one outer housing part in a timely manner and thereby increase the service life of the inner housing part and in particular the electronics. In this way, the at least one outer housing part can be designed as an expendable part which is inexpensive and can be easily exchanged.

The wear and/or the state of the at least one outer housing part can be reported to a condition monitoring system (CMS) which is connected. The condition monitoring system can then inform the maintenance personnel if the state of the outer housing part changes quickly or if a critical state has occurred. The personnel may be informed via an indicator on an automation interface such as a human-machine interface (HMI), a PC or a mobile terminal such as a tablet or smartphone, for example.

In a further advantageous embodiment of the invention, the means for registering wear comprise in this case at least one wire which is arranged in the at least one outer housing part and is connected to analysis electronics.

One or more wires may be embedded or incorporated in the at least one outer housing part, wherein the ends of the respective wire are routed to the analysis electronics via a contact plug, for example. The analysis electronics then determine the wear and/or the state of the at least one outer housing part, e.g. by analyzing the resistance of the wire. As soon as the expendable shell wears as far as the wire, the line is interrupted, wherein this line interruption can be reported by the analysis electronics as “worn outer housing part” in particular. It is further conceivable for a semiconductor wire to be used and for the resistance to be registered by the analysis electronics, said resistance being dependent on the temperature of the wire and hence the at least one outer housing part, in order then to determine the wear and/or the state of the at least one outer housing part.

In this case, a plurality of wires may be embedded at various depths of the at least one outer housing part in order to provide more precise information about the wear state. For example, at least two wires may be provided at different depths, wherein an interruption of the outer wire is not yet considered to be critical but may result in reordering of the respective outer part, for example. If the inner wire is also interrupted, the state of the respective outer housing part is critical and the outer housing part is exchanged.

In a further advantageous embodiment of the invention, the means for registering wear comprise a magnet, a metal foil, a metal piece and/or an RFID tag which is arranged in the at least one outer housing part.

The wear state of the at least one outer housing part can also be determined by embedding magnets, metal foil/pieces or RFID tags in the at least one outer housing part. The relevant measuring principle here is that the magnet or metal piece or RFID tag is removed from the receiving range of an associated and suitable detector due to wear or becomes unusable due to incineration, destruction, erosion, mechanical deformation or disintegration. This is registered by the analysis electronics and can be reported as “worn outer housing part”. In this case, a plurality of such elements may again be provided at various depths of the at least one outer housing part in order to provide more precise information about the wear state.

Furthermore, the individual characteristics of the embedded mechanisms, e.g. the oscillatory characteristics or a unique ID, can also be used for the purpose of unambiguously identifying the at least one outer housing part or electronics protection housing. It is consequently possible unequivocally to recognize that an incorrect or imitation part in the form of an illegal copy has been plugged in, thereby ensuring both protection against product piracy and high quality of the parts used.

The proposed system, comprising the electronics protection housing with the means for registering wear and a connected information system as described above, allows efficient and effective monitoring of the electronics protection housing. The connected information system may be embodied as a condition monitoring system (CMS), for example, which is integrated into a more extensive IT system and is able in particular to signal an alarm to operating/maintenance personnel and possibly to reorder a new outer housing part automatically in the case of a worn outer housing part.

In principle, the inventive electronics protection housing and/or the electronics disposed therein can also be supplied with energy by means of a cable, said cable being routed into the electronics protection housing from outside. It is conceivable to route the cable within the medium line in this case.

The invention is described and explained in greater detail below with reference to the exemplary embodiments illustrated in the figures, in which:

### BRIEF DESCRIPTION OF THE DRAWINGS

FIG. 1 shows a first exemplary embodiment of the inventive electronics protection housing,

FIG. 2 shows a second exemplary embodiment, and

FIG. 3 shows a third exemplary embodiment.

### DESCRIPTION OF EMBODIMENTS

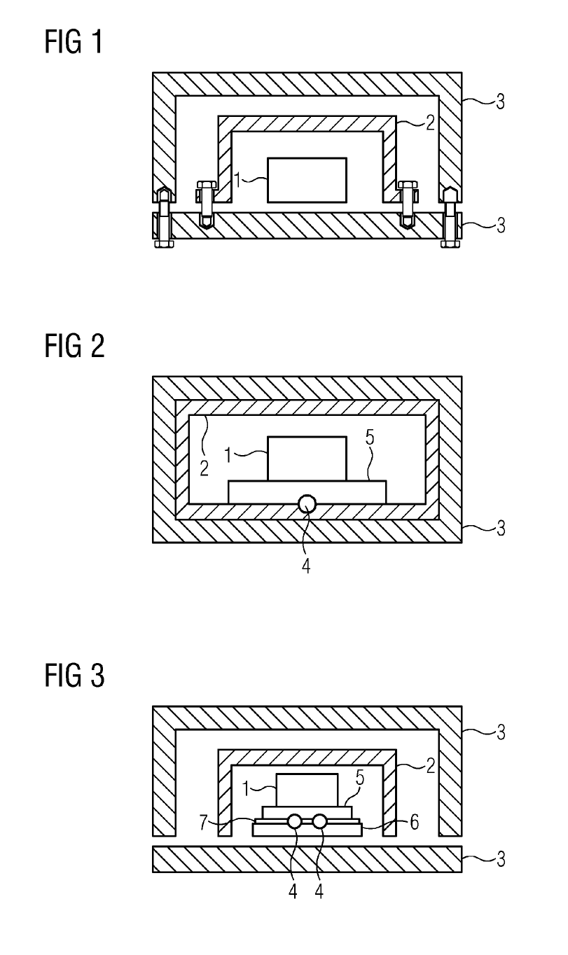

FIG. 1 shows a first exemplary embodiment of the electronics protection housing according to the invention. The electronics protection housing has an inner housing part 2, which partially encloses electronics 1, and an outer housing part 3, which in the context of this exemplary embodiment comprises a first part having a U-shaped cross-section and a second part that is designed as a plate. In this case, the first part and the second part of the outer housing part 3 are connected together by means of a mechanically removable screw connection. The two-part outer housing part 3 encloses the inner housing part 2, and electronics 1 are arranged in the inner housing part 2. The inner housing part 2 is fastened to the outer housing part 3 by means of a mechanically removable screw connection.

According to the invention, the outer housing part 3 has at least one layer comprising a renewable raw material, and the inner housing part 2 has at least one layer comprising a synthetic material having a temperature resistance of at least up to 150° C.

FIG. 2 shows a second exemplary embodiment of the electronics protection housing according to the invention. For the purpose of protecting electronics 1, the electronics protection housing has an outer housing part 3 which has a layer comprising a renewable raw material, and an inner housing part 2 which has a layer comprising a synthetic material having a temperature resistance of at least up to 150° C. The inner housing part 2 at least partially encloses the electronics 1 and the outer housing part 3 at least partially encloses the inner housing part 2. The two parts are connected together by a mechanically removable connection which is not shown in further detail.

The electronics 1 are in thermal contact with a first heat sink 5, wherein a medium line 4 passes though the electronics protection housing and the medium line 4 is also in thermal contact with the first heat sink 5. For example, the medium line 4 may follow a straight-line course within the electronics protection housing, such that the medium line 4 enters the electronics protection housing on one side and leaves it again on the opposite side.

FIG. 3 shows a third exemplary embodiment of the electronics protection housing according to the invention. Electronics 1 are arranged in the electronics protection housing, and are in thermal contact with a first heat sink 5. In this case, provision is made for a medium line 4 to which the first heat sink 5 can release waste heat because the first heat sink 5 is in thermal contact with the medium line 4 and the medium therein. For example, the medium line may be so designed as to have a U-shape within the electronics protection housing, such that it enters the electronics protection housing on one side, exhibits a U-shaped bend within the electronics protection housing, and then leaves the electronics protection housing on the same side again.

Provision is additionally made for a second heat sink 6, which can likewise release waste heat to the medium line 4 or a medium therein. An insulation layer 7 is provided between the second heat sink 6 and the first heat sink 5 in this case, thermally insulating both heat sinks from each other, wherein the medium line 4 is provided in the plane of the insulation layer 7 in the context of the exemplary embodiment. The insulation layer 7 therefore effects a thermal decoupling of the first heat sink 5 from the second heat sink 7, such that waste heat from the electronics 1 can be passed only to the medium line 4 via the first heat sink 5, and not to the second heat sink 6. Furthermore, the insulation layer 7 prevents a possible transfer of heat from outside the electronics protection housing via at least the outer housing part 3 and the second heat sink 7 to the first heat sink 5 and then to the electronics 1, since the insulation layer 7 thermally separates the second heat sink 6 from the first heat sink 5.

The arrangement comprising the electronics 1, the first heat sink 5, the insulation layer 7 and the second heat sink 6 is partially enclosed by an inner housing part 2 which has a layer comprising a synthetic material having a temperature resistance of at least up to 150° C., wherein the inner housing part 2 is enclosed by an outer housing part 3 which is designed in two parts as per the first exemplary embodiment and has a layer comprising a renewable raw material. In this case, the outer housing part 3 is fastened to the inner housing part 2 by means of a mechanically removable connection which is not illustrated in further detail, e.g. a screw connection or clamped joint, etc.

In each of the exemplary embodiments, for example, the electronics 1 can be supplied with electrical energy by means of a Peltier element, by means of a turbine in the medium line 4 and means for converting the rotational movement of the turbine into electrical energy, or by means of a piezoelectric element or a dielectric elastomer.

Furthermore, the electronics protection housing may have means for registering wear of the outer housing part 3, said means comprising e.g. a wire which is disposed at least partially in the outer housing part and is connected to analysis electronics. Likewise for this purpose, provision may be made for a plurality of wires which run in the outer housing part 3 at different depths relative to the outer surface of the outer housing part 3 and therefore allow any advancement of the wear of the outer housing part 3 to be registered. The means for registering the wear of the outer housing part 3 may also comprise a magnet, a metal foil, a metal piece and/or an RFID which is arranged in the outer housing part 3.

In summary, the invention relates to an electronics protection housing for accommodating electronics. In order to provide an electronics protection housing which reliably protects electronics therein from heat or hot liquids or solids, the proposed electronics protection housing has an inner housing part, by means of which the electronics can be at least partially enclosed, and at least one outer housing part, which at least partially encloses the inner housing part and which can be fastened to the inner housing part by means of a mechanically removable connection, wherein the at least one outer housing part has at least one layer comprising a renewable raw material, and wherein the inner housing part has at least one layer comprising a material having a temperature resistance of at least up to 150° C.

1. An electronics protection housing for accommodating electronics comprising:
an inner housing part, configured and located to at least partially enclose the electronics; and
at least one outer housing part, which at least partially encloses the inner housing part and is configured to be fastened to the inner housing part and a mechanically removable connection connecting the inner and outer housing parts;
the at least one outer housing part includes at least one layer comprising a renewable raw material; and
the inner housing part includes at least one layer comprising a material having a temperature resistance of at least up to 150° C.

2. The electronics protection housing as claimed in claim 1, wherein both of the at least one inner housing part and the at least one outer housing part are at least sectionally permeable to radio waves for enabling wireless communication.

3. The electronics protection housing as claimed in claim 1, further comprising, a protective gas is provided within at least one of the outer housing part and the inner housing part.

4. The electronics protection housing as claimed in claim 1, wherein the at least one layer comprises a renewable raw material selected from the group consisting of at least one of wood, wood foam, paperboard, cardboard, a fiberboard composite material and a mixture of at least two of these materials.

5. The electronics protection housing as claimed in claim 1, wherein the at least one layer comprising the material having a temperature resistance of at least up to 150° C. includes at least one of polytetrafluoroethylene, polyphenylene sulfide, silicone rubber, polyimide, ethylene propylene copolymer, cyclic olefin copolymer, polyetherimide, polyethersulfone, polyhydroxyalkanoate, polyhydroxybutyrate, polysulfone, or a mixture of at least two of these materials.

6. The electronics protection housing as claimed in claim 1, further comprising, at least one medium line oriented and configured to lead into the inner housing part from outside the electronics protection housing and configured for a liquid or gaseous medium to flow therethrough.

7. The electronics protection housing as claimed claim 1, further comprising, a first heat sink, thermally connected to the electronics and to which the connected electronics releases waste heat.

8. The electronics protection housing as claimed in the claim 6, wherein the at least one medium line is arranged at the first heat sink in such a way that the first heat sink releases waste heat to the medium.

9. The electronics protection housing as claimed in claim 8,
further comprising a second heat sink;
the at least one medium line is arranged at the second heat sink in such a way that the second heat sink releases waste heat to the medium; and
an insulation layer comprising a synthetic material having a temperature resistance of at least up to 150° C. arranged between the first heat sink and the second heat sink.

10. The electronics protection housing as claimed in claim 5, further comprising a Peltier element configured for supplying the electronics, wherein the Peltier element has one side in thermal contact with the at least one medium line.

11. The electronics protection housing as claimed in claim 5, further comprising a turbine rotatably disposed in the at least one medium line, and means at the turbine configured for converting a rotational movement of the turbine into electrical energy,
wherein the electronics is supplied with electrical energy by the turbine and the means for converting.

12. The electronics protection housing as claimed in claim 1, further comprising means for converting mechanical energy of the electronics protection housing into electrical energy for a purpose of supplying the electronics with electrical energy.

13. The electronics protection housing as claimed in claim 12, further comprising the means for converting mechanical energy of the electronics protection housing into electrical energy comprise at least one of a piezoelectric element and a dielectric elastomer.

14. The electronics protection housing as claimed in claim 1, further comprising means for registering wear of the at least one outer housing part.

15. The electronics protection housing as claimed in claim 14, further comprising the means for registering wear comprise at least one wire arranged in the at least one outer housing part and connected to analysis electronics.

16. The electronics protection housing as claimed in claim 14, wherein the means for registering wear comprise at least one of a magnet, a metal foil, a metal piece and an RFID tag which is arranged in the at least one outer housing part.

17. A system comprising:
an electronics protection housing as claimed in claim 14; and
a connected information system, to which the means for registering wear is configured to transmit information concerning the wear of the at least one outer housing part.

18. The system of claim 17, wherein the information transmitted comprise a signal of an alarm to personnel.

19. An electronics protection housing for accommodating electronics, comprising:
an inner housing part, configured and located to at least partially enclose the electronics;
at least one outer housing part, which at least partially encloses the inner housing part and is configured to be fastened to the inner housing part and a mechanically removable connection connecting the inner and outer housing parts; and
both of the at least one inner housing part and the at least one outer housing part are at least sectionally permeable to radio waves for enabling wireless communication.

20. An electronics protection housing for accommodating electronics-, comprising:
an inner housing part, configured and located to at least partially enclose the electronics; and
at least one outer housing part, which at least partially encloses the inner housing part and is configured to be fastened to the inner housing part and a mechanically removable connection connecting the inner and outer housing parts;
at least one of the housing parts includes at least one layer comprising a renewable raw material; and
the other of the housing parts includes at least one layer comprising a material having a temperature resistance of at least up to 150° C.
